(19) United States
(12) Patent Application Publication
(10) Pub. No.: US 2012/0234391 A1
(43) Pub. Date: Sep. 20, 2012

(54) GLASS-COATED FLEXIBLE SUBSTRATES FOR PHOTVOLTAIC CELLS

(75) Inventors: Salah Boussaad, Wilmington, DE (US); Damien Francis Reardon, Wilmington, DE (US)

(73) Assignee: E. I. DU PONT DE NEMOURS AND COMPANY, Wilmington, DE (US)

(21) Appl. No.: 13/232,233

(22) Filed: Sep. 14, 2011

Related U.S. Application Data
(60) Provisional application No. 61/382,502, filed on Sep. 14, 2010.
(60) Provisional application No. 61/382,504, filed on Sep. 14, 2010.
(60) Provisional application No. 61/382,505, filed on Sep. 14, 2010.
(60) Provisional application No. 61/382,509, filed on Sep. 14, 2010.

(51) Int. Cl. H01L 31/0264; B05D 7/14; B05D 3/02; B32B 15/04

(52) U.S. Cl. 136/262; 136/264; 428/433; 427/397.7

(57) ABSTRACT

The present disclosure relates to a method of manufacturing of a glass coated material that is suitable for use in the manufacture of flexible solar cells and other electronic devices. The invention is also to articles comprising the flexible solar cells described herein.

### FIELD OF THE INVENTION

The present disclosure relates to a method of manufacturing a metal oxide and glass coated metal product. This invention also relates to a coated metallic substrate material that is suitable for manufacturing flexible solar cells and other articles in which a passivated stainless steel surface is desirable.

### BACKGROUND

Photovoltaic cells are made by depositing various layers of materials on a substrate. The substrate can be rigid (e.g., glass or a silicon wafer) or flexible (e.g., a metal or polymer sheet).

The most common substrate material used in the manufacture of thin-film Cu(In,Ga)Se₂ (CIGS) solar cells is soda lime glass. Soda lime glass contributes to the efficiency of the solar cell, due to the diffusion of an alkali metal (primarily sodium) from the glass into the CIGS layer. However, batch production of CIGS on glass substrates is expensive and glass is typically too rigid to be adapted to a roll-to-roll process. The disadvantages of using common glass substrates for the photovoltaic cells have motivated the search for substrates that are flexible, tolerant of the high temperatures used to create the photoactive layers, inexpensive and suitable for use in roll-to-roll processes.

Several materials have been tested as substrate materials for flexible CIGS solar cells, including polymers such as polyimide and metals such as molybdenum, aluminum and titanium foils. The substrate should be tolerant of temperatures up to 800° C. and reducing atmospheres. A metallic substrate must also be electrically insulated from the back contact to facilitate production of CIGS modules with integrated series connections. It is desirable for the coefficient of thermal expansion (CTE) of the substrate material to be as close as possible to the CTE of the electrical insulating material to avoid thermal cracking or delamination of the insulating material from the substrate.

There is also interest in developing CZTS-Se based solar cells, analogous to CIGS solar cells except that CIGS is replaced by CZTS-Se, where “CZTS-Se” encompass all possible combinations of Cu₂ZnSn(S,Se)₄, including Cu₂ZnSnS₄, Cu₂ZnSnSe₄, and Cu₂ZnSnSₓSe₄₋ₓ, where 0≦x≦4.

Since polymers are generally not thermally stable above 450° C., coated metal substrates have been desirable since temperatures of above 450° C. are routinely achieved in many applications, including photovoltaic cells.

To form an electrically insulating layer on the metal substrate, it is known to deposit SiOₓ or SiO₂ onto metal strips in batch-type deposition processes.

It is also known to coat a metallic base with a first coat of an alkali silicate, optionally containing alumina particles. A second coat of silicone can be applied onto the first coat of an alkali silicate.

In another approach, a stainless steel plate is contacted with a solution of a metal alkoxide, an organoalkoxysilane, water, and thickeners such as alkoxy silane in an organic solvent, then dried and calcined.

A method for producing a substrate for solar batteries has also been disclosed in which a first insulating layer is formed on a metal plate (e.g., a stainless steel plate). Then the surface of the metal plate exposed by pinholes in the first insulating layer is oxidized by heating the metal plate in air. A second insulating layer is then applied over the first insulating layer.

A coated steel substrate useful as a substrate for flexible CIGS solar cells has been disclosed that comprises a stainless steel strip coated with a sodium-doped alumina layer onto which an electrically conducting layer of molybdenum has been deposited.

A process for forming an electrically insulating layer of aluminum oxide on ferritic stainless steel has been disclosed. The alumina-coated stainless steel sheet was used as a substrate for an amorphous silicon solar battery manufactured by plasma chemical vapor deposition (P-CVD) on the oxide film.

In co-pending application serial number (CL4932), is disclosed a steel substrate having a coating of glass, and having disposed between the glass and the steel layers a layer of alumina.

There remains a need for process to produce a substrate that has the flexibility of a metal, the surface properties of glass, and can be used in a roll-to-roll process for the manufacture of CIGS cells, without the need for a interlayer coating between the glass coating and the metal substrate.

### SUMMARY OF THE INVENTION

In one aspect, this invention is a process comprising the steps: a) depositing a glass precursor directly on to at least a portion of a surface of a flexible substrate, wherein there are no intervening layers between the glass precursor and the substrate surface; and
b) heating the glass precursor to form a glass layer on the surface of the metal substrate, wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect the present invention is a process comprising the steps of:
a) depositing a glass precursor directly on to at least a portion of a surface of a flexible metal substrate, wherein there are no intervening layers between the glass precursor and the metal substrate surface, wherein the metal is a metal selected from the group consisting of aluminum, titanium, molybdenum, nickel, vanadium, chromium, silver and gold; and
b) heating the glass precursor to form a glass layer on the surface of the metal substrate, wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect the present invention is a multilayer article comprising:
a) a multilayer composite comprising a flexible metal layer having deposited directly on a surface thereof a glass layer, wherein there are no intervening layers disposed between the glass layer and the surface of the flexible metal layer, and wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect, this invention is a process comprising the steps:
a) depositing a glass precursor directly on to at least a portion of a surface of a flexible polymeric substrate, wherein there are no intervening layers between the glass precursor and the polymeric substrate surface; and
b) heating the glass precursor to form a glass layer on the surface of the metal substrate, wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect the present invention is a multi-layer article comprising:
a) a flexible polymeric substrate; and
b) a glass layer disposed directly on at least a portion of a surface of the flexible polymeric substrate, wherein there are no intervening layers disposed between the glass layer and the surface of the flexible polymeric substrate, and wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect, this invention is a process comprising the steps: a) depositing a glass precursor directly on to at least a portion of a surface of a flexible metal substrate, wherein there are no intervening layers between the glass precursor and the metal substrate surface; and
b) heating the glass precursor to form a glass layer on the surface of the metal substrate, wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these and wherein the sodium component is present in an amount of from about 1 to about 25% by weight of the glass layer.

In one aspect, this invention is a multi-layer article comprising:
a) a flexible metal substrate comprising 1 to 10 wt % aluminum; and
b) a glass layer disposed directly on at least a portion of a surface of the metal substrate, wherein there are no intervening layers disposed between the glass layer and the surface of the metal substrate, and wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these, and wherein the sodium component of the glass layer is present in an amount of from about 1 to about 25% by weight of the glass layer.

In one aspect the present invention is a process comprising the steps:
a) depositing a glass precursor directly on to at least a portion of a surface of a stainless steel substrate, wherein there are no intervening layers between the glass precursor and the metal surface; and
b) heating the glass precursor to form a glass layer on the surface of the metal substrate, wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

In one aspect the present invention is a multi-layer article comprising:
a) a stainless steel substrate comprising 1 to 10 wt % aluminum; and
b) a glass layer disposed directly on at least a portion of a surface of the metal substrate, wherein there are no intervening layers disposed between the glass layer and the surface of the metal substrate, and wherein the glass layer comprises SiO₂, Al₂O₃, Na₂O, and B₂O₃, and optionally an oxide selected from the group consisting of Li₂O, BeO, MgO, BaO, K₂O, CaO, MnO, NiO, SrO, FeO, Fe₂O₃, CuO, Cu₂O, CoO, ZnO, PbO, GeO₄, SnO₂, Sb₂O₃, Bi₂O₃, an oxide of any lanthanide metal, or mixtures of any of these.

### DETAILED DESCRIPTION

In one embodiment, the present invention is a process for depositing and/or forming a glass layer on the surface of a flexible substrate. It can be desirable to impart glass-like properties to the surface of flexible materials in order to overcome at least some disadvantages of using common glass substrates in, for example, photovoltaic cells.

A flexible substrate of the present invention can be a flexible metal substrate or a polymeric substrate. Flexible metal substrates suitable for inclusion in the present invention can include stainless steel, aluminum, titanium, and molybdenum, nickel, vanadium, chromium, silver and gold, for example. Flexibility in a metal substrate can be dependent on the intrinsic properties of the specific metal, as well as on the bulk properties such as thickness. Extrinsic conditions, such as temperature for example, can affect flexibility. For the purposes of the present invention, flexibility can be loosely described as the extent to which the substrate will allow utilization of roll-to-roll processes.

A flexible substrate of the present invention can be a flexible polymeric substrate. Polymeric substrates suitable for use in the present invention can include polyimide polymers and polyethyleneterephthalate (PET) polymers, for example. All polymers are not suitable for use herein. Polymers such as PET can degrade at the high temperatures used in the process of the present invention. However, in one embodiment, the present invention is a process to make such heat-degradable polymers suitable for use in the practice of the present invention, whereby the high temperature is localized only at the surface of the polymer and whereby such localization of heating can substantially reduce the negative effect of high temperature processing on the degradable polymer by avoiding substantial thermal degradation in other regions of the polymer.

In one embodiment, the present invention is an article comprising a glass-coated polymer composite layer. Glass-coated polymer composite layers can be useful in electronic devices or as a component of a photovoltaic cell, for example. For example, a glass-coated PET composite layer can be useful as a barrier layer in a photovoltaic cell. A glass-coated polyimide composite layer can be useful as a substrate layer in a photovoltaic cell for deposition of thin-film photovoltaic cells.

Due to the process temperatures required for firing the glass precursor coating and forming a glass layer on the flexible substrate, a suitable substrate must be able to withstand processing temperatures of greater than 250° C. up to about 800° C.

One aspect of this invention is a process comprising:
a) depositing a glass precursor on at least a portion of a surface of a stainless steel substrate; and
b) heating the glass precursor to form a glass layer on at least a portion of the stainless steel substrate, wherein the glass layer comprises SiO₂, Al₂O₃, Na₂O, and B₂O₃, and optionally an oxide selected from the group consisting of MgO, K₂O, CaO, PbO, GeO₄, SnO₂, Sb₂O₃, Bi₂O₃ or any oxide of a lanthanide metal

This process is useful for passivating a surface of the stainless steel substrate. The passivation may protect the surface from chemical attack. The glass layer may serve as a thermal and/or electrical insulating layer, or also as an ion barrier, preventing detrimental doping of CIGS from iron, chromium, vanadium, nickel, titanium, phosphorus, manganese, molybdenum, niobium (or columbium) upon thermal processing of solar cells at elevated temperatures (ion migration prevention at 600° C. has been characterized by ESCA). An additional desirable property the glass passivation layer offers is leveling of the stainless steel surface to minimize shunting of the solar cell (planarization Ra<20 nm can be achieved and have been measured).

By passivation, in the present invention, it is meant that the stainless steel is prevented from undesirable interaction with the CIGS layer in a photovoltaic cell. For example, a passivating layer of the present invention acts to: (1) prevent ion contamination of the CIGS layer by stainless steel or other flexible substrate; (2) smooth irregularities in the surface of the stainless steel or other flexible substrate; and (3) provide electrical insulation of the CIGS layer from the stainless steel layer to enable monolithic stacking of a photovoltaic cell.

This process can be conducted batch-wise or as a continuous process, e.g., in a roll-to-roll process.

Stainless Steel Substrate

Suitable stainless steel substrates can be in the form of sheets, foils or other shapes. Sheets and foils are preferred for roll-to-roll processes. Suitable stainless steel typically comprises: 13-22 wt % chromium; 1.0-10 wt % aluminum; less than 2.1 wt % manganese; less than 1.1 wt % silicon; less than 0.13 wt % carbon; less than 10.6 wt % nickel; less than 3.6 wt % copper; less than 2 wt % titanium; less than 0.6 wt % molybdenum; less than 0.15 wt % nitrogen; less than 0.05 wt % phosphorus; less than 0.04 wt % sulfur; and less than 0.04 wt % niobium, wherein the balance is iron.

In some embodiments, the stainless steel comprises: about 13 wt % chromium; 3.0-3.95 wt % aluminum; less than 1.4 wt % titanium; about 0.35 wt % manganese; about 0.3 wt % silicon; and about 0.025 wt % carbon, wherein the balance is iron.

In some embodiments, the stainless steel comprises: about 22 wt % chromium and about 5.8 wt % aluminum, wherein the balance is iron.

For the purposes of the present invention, quantities of any component that are so small that they cannot be measured quantitatively by known and/or conventional methods are not considered to be within the scope of the present invention and, therefore, when only an upper compositional range limit is provided it should be understood to mean that a measureable lower limit is within the scope of the invention.

Other Metals

In one embodiment, the present invention is a process for depositing a glass layer or a glass precursor layer on the surface of a flexible metal substrate other than stainless steel. Suitable other metals for the purposes of the present invention include, for example: aluminum, titanium, and molybdenum, nickel, vanadium, chromium, silver and gold

Polymer Substrates

In one embodiment, the present invention is a process for depositing a glass layer or a glass precursor layer on the surface of a flexible polymer substrate. A polymer substrate suitable for the practice of the present invention is a thermoplastic or thermoset polymer that is capable of being processed at temperatures above 250° C. without substantial degradation to the polymer chain, or significant deterioration of the desired and/or required properties of the polymer for the intended use of the glass/polymer multilayered article. For example, polyethyleneterephthallate (PET) polymers and polyimide polymers can be useful in the practice of the present invention. It can be necessary or desirable to heat only the surface of certain polymers, that is, only where the polymer surface will come into contact with the glass layer or glass precursor layer, in order to avoid potential degradation of the polymer in other regions of the polymeric substrate.

Glass Precursor Layer

In one aspect of this invention, the substrate is coated with a glass precursor layer, followed by steps of drying and firing the glass precursor layer to form a glass layer on the stainless steel substrate. As described below, the thickness of the glass layer can be increased by carrying out multiple cycles of coating-and-drying before firing, or by carrying out several cycles of coating-drying-and-firing.

The glass layer is formed by coating the surface of the stainless steel substrate, in whole or in part, with a glass precursor composition. The precursor composition can comprise: (1) a form of silicon that is soluble in at least one solvent; (2) an aluminum compound; (3) a boron-containing compound; (4) a sodium salt and, optionally (5) a potassium salt.

A soluble form of silicon can be, for example, silicon tetraacetate, silicon tetrapropionate, bis(acetylacetonato) bis(acetato) silicon, bis(2-methoxyethoxy) bis (acetato) silicon, bis(acetylacetonato) bis(ethoxy) silicon, tetramethylorthosilicate, tetraethylorthosilicate, tetraisopropylorthosilicate, or mixtures thereof).

An aluminum compound can be, for example: tris(acetylacetonato) aluminum, aluminum methoxide, aluminum ethoxide, aluminum isopropoxide, aluminum n-propoxide, or mixtures thereof) is added as well as a trialkylborate (for example, trimethylborate, triethylborate, tripropylborate, trimethoxyboroxine, or mixtures thereof.

A precursor for sodium oxide can be, for example, sodium acetate, sodium propionate, sodium silicate, sodium alkoxides, sodium borate, sodium tetraphenyl borate, or mixtures thereof.

In one embodiment of the present invention a sodium source is included in the glass precursor layer in order that the glass layer functions as a sodium transport layer, to provide a source of sodium to an adjacent layer in an electronic device such as a photovoltaic cell and improve the efficiency of the device. The doping with sodium can be accomplished by doping the glass precursor layer with sufficient sodium to provide from about 0.01 atomic % to about 5 atomic % sodium to the conductive layer of a photovoltaic cell. The sodium source can be ionic or covalent. Migration of sodium from the glass layer to the semi-conductive layer can provide the level of sodium required in the semi-conductive layer to exhibit improved efficiency relative to a cell wherein sodium is not present in the semi-conductive layer at the same level as described herein.

The sodium source can be, for example, any salt of sodium that can be dissolved or made soluble or dispersible in the glass precursor composition of the present invention.

The optional potassium salt can be, for example, potassium acetate, potassium propionate, potassium methoxide, potassium ethoxide, potassium isopropoxide, or mixtures thereof.

To form the glass precursor composition, the soluble silicon can be dissolved in a solvent such as, for example: (1) a C1-C10 alcohol (for example methanol, ethanol, 1-propanol, 2-propanol, 1-butanol, 2-butanol, isomers of 1-butanol, 1-pentanol, 2-pentanol, 3-pentanol, isomers of 1-pentanol, 1-hexanol, 2-hexanol, 3-hexanol, isomers of 1-hexanol, 1-heptanol, isomers of 1-heptanol, or mixtures thereof); (2) an acid (for example, acetic acid, propionic acid, hydrochloric acid, nitric acid, sulfuric acid, or mixtures thereof) and (3) water to obtain a solution of dissolved silicon solution. Water can be included in an amount of from 0 to 4 mole equivalents, with respect to silicon. Minimal amounts of the solvent can be used, with the caveat that the amount should be sufficient and effective to form a solution of the components.

The sodium salt can be dissolved in the same C1-C10 alcohol used to prepare the initial silicon solution, and added to the silicon solution. In some embodiments, the glass precursor formulation is filtered prior to coating the stainless steel substrate. In some embodiments, the composition of the glass precursors in the formulation is in an element ratio of about 100 (Si) to 45 (B) to 26 (Na) to 3 (Al).

In one embodiment, the precursor composition can be prepared by dissolving a silicon oxide precursor (for example, tetraethylorthosilicate) in a minimum amount of 1-butanol, or a 1:1 mixture of 1-butanol and acetic acid, and stirring. To this solution, two mole equivalents of water are added and the solution is refluxed for one hour. An aluminum oxide precursor (for example, tris(acetylacetonato)aluminum), a boron oxide precursor (for example, triethyl borate) and a sodium oxide precursor (for example, sodium tetraphenylborate) in 1-butanol, are added. Once the precursors are dissolved, more solvent is added to obtain the desired concentration.

The glass layer can optionally include an oxide of lithium, magnesium, potassium, calcium, barium, lead, germanium, tin, antimony, bismuth or any lanthanide. Suitable precursors for Li₂O, MgO, BaO, K₂O, CaO, PbO, GeO₄, SnO₂, Sb₂O₃, Bi₂O₃ or any oxide of a lanthanide metal can include the respective acetates, for example: potassium acetate, calcium acetate, lead acetate, germanium acetate, tin acetate, antimony acetate, and bismuth acetate. Other oxide precursors can be used, as may be known to one of ordinary skill in the art.

Silicon alkoxides (for example, a silicon tetraalkylorthosilicate) and aluminum alkoxides (for example, aluminum isopropoxide) can also be used in the preparation of the glass precursor compositions.

Optionally, borosilicate glass nanoparticles can be added to the formulation.

Depositing a coating of the glass precursor composition onto the stainless steel substrate can be carried out by any known and/or conventional means, including bar-coating, spray-coating, dip-coating, microgravure coating, or slot-die coating. One of ordinary skill in the art would appreciate the benefits and/or disadvantages of any of these conventional coating means, and could choose an appropriate coating method based on the particulars of the process parameters under consideration.

After coating the glass precursor composition onto the stainless steel substrate, the precursor is typically dried in air at 100 to 150° C. to remove solvent. In some embodiments, the dried glass precursor layer is then fired in air or an oxygen-containing atmosphere at 250 to 800° C. to convert the glass precursor layer to a fired glass layer. By “firing” it is meant that the glass precursor layer is heated above the decomposition temperature of the precursors in an oxidizing atmosphere to:
1) remove any organic ligands used to solubilize the glass precursors in the coatable solution and;
2) oxidize silicon, aluminum, boron and sodium components of the solution to their respective oxide form and;
3) form a thin, dense glass film on the substrate.

It can be desirable to increase the thickness of the fired glass layer by carrying out additional cycles of (1) depositing the glass precursor on surface of the substrate (coating) and (2) drying prior to firing.

The cycle of (1) coating followed by (2) drying can be repeated numerous times, depending on the thickness of the glass layer that is desirable, and the number of repetitions that are needed to obtain the desired thickness. Typically the desired thickness can be obtained with 2-5 repetitions of the coating/drying cycle.

The thickness of the fired glass layer can be from about 10 nm to several micrometers in thickness. In certain embodiments, the thickness of the glass fired layer can be in the range of from about 1 nm to several microns in thickness. In some uses -- for example when used in a photovoltaic cell -- it can be desirable to increase the flexibility of the fired glass layer by reducing its thickness to within the range of from about 10 nm to about several microns, or from about 25 nm to about 10 micrometers, or from about 50 nm to about 5 micrometers, or less than about 3 micrometers. However, the desired thickness for flexibility can depend on the application, the composition, or other factors. For example, in some applications pinholes in the glass layer can be desirable and it can therefore be desirable to reduce the thickness of the glass layer to allow pinholes. In other applications the thickness can be increased to provide optimum insulation, therefore, minimum pinholes in the glass layer. In any event, the purpose of the present invention is to provide flexibility to a glass layer whereby normal handling does not produce cracks in the glass. Cracks, even if observable only with a microscope, are undesirable. To avoid cracking in the glass layer, an upper thickness limit for the glass layer may be reached at about 5 micrometers, or at about 4 micrometers, or at about 3 micrometers.

Optionally, the steps of (1) coating, (2) drying, and (3) firing can be repeated 2 or more times. This can also increase the total thickness of the fired glass layer. Multiple intermediate firing steps facilitate removal of any carbon that might be present in the glass precursor components, and therefore multiple firing steps can be preferred.

Also optionally, the drying step can be skipped and the glass precursor layer can be pre-fired at lower temperature than the firing step, and then subsequently fired. It can be advantageous to pre-fire the glass precursor layer to, for example: drive off solvent at a faster rate; facilitate gellation of the glass precursor layer; and/or to facilitate other interactions among the components of the glass precursor layer. Any combination of drying, pre-firing and firing steps can be repeated multiple times to get the thickness or other properties desirable in the final glass layer.

In some embodiments, water is added to the precursor mixture prior to the coating step. This increases the viscosity of the glass precursor composition and facilitates the formation of glass layers of 50 nm to 2 microns thickness in one coating and drying cycle.

Both the firing step(s) and drying step(s) are typically conducted in air to ensure complete oxidation of the glass precursors. The presence of elemental carbon, carbonate intermediates or reduced metal oxides in the glass layer may lower the breakdown voltage of the insulating layer.

After firing, the glass layer can comprise: greater than 70 wt % silica; less than 10 wt % alumina; 5-15 wt % of a boron oxide; and less than 10 wt % of oxides of sodium and/or potassium. In one embodiment, the fired glass layer comprises: about 81 wt % SiO₂, about 13 wt % B₂O₃, from about 1 wt % up to about 4 wt % Na₂O, and about 2 wt % Al₂O₃.

In other embodiments of the present invention, the glass layer can comprise the sodium component in an amount greater than about 4% by weight of the glass layer. For example, the sodium component can be present in an amount of from about 4% to about 25% by weight of the glass layer, or from about 4% to about 18% by weight of the glass layer, or from about 4% to about 16% by weight of the glass layer.

In some embodiments, the glass precursor compositions are selected to provide coefficients of linear thermal expansion (CTE) of the glass layers to be close to those of the Mo and CIGS (or CZTS-Se) layers to reduce stress on the Mo and CIGS (or CZTS-Se) layers and to reduce film curling. In some embodiments, the CTE of the borosilicate glass is about 3.25×10⁻⁶/° C. to provide a good match to the CTE of the Mo layer (about 4.8×10⁻⁶/° C.) and the CIGS layer (about 9×10⁻⁶/° C.).

One aspect of this invention is a multi-layer article comprising:
a) a stainless steel substrate comprising 1 to 10 wt % aluminum;
b) a glass layer disposed directly on at least a portion of the stainless steel, wherein the glass layer comprises SiO₂, Al₂O₃, Na₂O, B₂O₃, and optionally an oxide selected from the group consisting of LiO, MgO, K₂O, BaO, CaO, PbO, GeO₄, SnO₂, Sb₂O₃, Bi₂O₃ and any oxide of a lanthanide metal.

The stainless steel substrate and glass layer are as described above.

This multilayer article can be used as the substrate for the manufacture of electronic devices, such as for example, organic light emitting diode display applications, white light organic light emitting diode applications, photovoltaic applications. Such multilayer articles can also be used in medical devices such as heart valves.

In some embodiments, the multilayer article further comprises:
d) a conductive layer disposed on at least a portion of the glass layer.

In some embodiments, the multilayer article further comprises:
e) a photoactive layer disposed on the conductive layer;
f) a CdS layer disposed on the photoactive layer; and
g) a transparent conductive oxide disposed on the CdS layer.

Such multilayer articles can be used in photovoltaic cells, for example.

Suitable conductive layers comprise materials selected from the group consisting of metals, oxide-doped metals, metal oxides, organic conductors, and combinations thereof. A conductive metal layer can be deposited onto the glass layer through a vapor deposition process or electroless plating. Suitable metals include Mo, Ni, Cu, Ag, Au, Rh, Pd and Pt. The conductive metal layer is typically 200 nm-1 micron thick. In one embodiment, the conductive material is molybdenum oxide-doped molybdenum.

In some embodiments, the multilayer article comprises organic functional layers, e.g., organic conductors such as polyaniline and polythiophene. In such embodiments, the multilayer article is generally not heated above 450° C., or 400° C., or 350° C., or 300° C., or 250° C., or 200° C., or 150° C., or 100° C. after the organic functional layer has been deposited.

Suitable photoactive layers include CIS (cadmium-indium-selenide), CIGS, and CZTS-Se.

The CIGS and CIS layers can be formed by evaporating or sputtering copper, indium and optionally gallium sequentially or simultaneously, then reacting the resulting film with selenium vapor. Alternatively, a suspension of metal oxide particles in an ink can be deposited on the conductive layer using a wide variety of printing methods, including screen printing and ink jet printing. This produces a porous film, which is then densified and reduced in a thermal process to form the CIGS or CIS layer. The processes described hereinabove are known and conventional in the art. In fact, any known or conventional process can be used to form the CIGS or CIS layers.

CZTS-Se thin films can be made by several methods, including thermal evaporation, sputtering, hybrid sputtering, pulsed laser deposition, electron beam evaporation, photochemical deposition, and electrochemical deposition. CZTS thin-films can also be made by the spray pyrolysis of a solution containing metal salts, typically CuCl, ZnCl₂, and SnCl₄, using thiourea as the sulfur source.

The CdS layer can be deposited by chemical bath deposition, for example. Other means that are known and/or conventional can be used.

A suitable transparent conductive oxide layer, such as doped zinc oxide or indium tin oxide, can be deposited onto the CdS layer by sputtering or pulsed layer deposition, for example. Other methods that are known and/or are conventional to one of ordinary skill in the art can be used.

### EXAMPLES

Examples for monolithic integration: the following general procedures were used in the Examples.

General Procedure

A 50.8 micrometer thick stainless steel foil (Ohmaloy® 30, 2-3 wt % aluminum, ATI Allegheny Ludlum) was annealed at 1000° C. in air for 15 hr to provide a coating of alumina on the surface of the stainless steel foil. The foil was then diced to size and argon plasma-cleaned (A.G. Services PE-PECVD System 1000) for 30 sec under the following conditions:
power=24.3 W
pressure=100.0 mTorr
throttle pressure=200.0 mTorr
argon gas flow=10.0 sccm

Preparation of a Precursor Composition Containing 0.75 M [Si]:

Tetraethylorthosilicate (3.9042 g, 18.74 mmol) was dissolved in 1-butanol (5.00 ml) and 5 ml of acetic acid containing 0.6725 ml of deionized water. The solution was refluxed for 1 h. To this solution, was added triethylborate (0.5247 g, 3.59 mmol) and tris(acetylacetonato) aluminum (0.1768 g, 0.55 mmol). Separately, a sodium tetraphenylborate (1.6553 g; 4.84 mmol) solution in 1-butanol (5 ml) was prepared and mixed with the silicon, aluminum, boron precursor 1-butanol solution. The solution was stirred and 1-butanol was added until a total volume of 25.00 ml was achieved. The glass precursor composition was filtered through a 2 micron filter prior to coating the stainless steel substrate.

Rod-Coating:

The substrates were rod-coated using a #20 bar on a Cheminstrument® motorized drawdown coater at room temperature in a clean room environment (class 100). The coated substrate was then dried at room temperature for 30 s and subsequently at 150° C. for 2 min to form a dried glass precursor layer on the annealed stainless steel substrate. This procedure was used one or more times in each of the examples described below.

Firing:

After drying, the coated substrates were fired to 500° C. for 2 min at a ramp rate of 8° C./s using a modified Leyboldt L560 vacuum chamber outfitted with cooled quartz lamp heaters above and below the coated substrate, with an air bleed of 20 sccm (total pressure 1 mTorr). Out-gassing was monitored using a residual gas analyzer. This procedure was used one or more times in each of the examples described below.

Determination of Dielectric Strength:

Breakdown voltage was measured with a Vitrek 944i dielectric analyzer (San Diego, Calif.). The sample was sandwiched between 2 electrodes, a fixed stainless steel rod as cathode (6.35 mm diameter and 12.7 mm long) and a vertically sliding stainless steel rod as anode (6.35 mm diameter and 100 mm long). The mass of the sliding electrode (32.2 g) produced enough pressure so the anode and cathode form good electrical contact with the sample. The voltage was ramped at 100 V/s to 250 V and kept constant for 30 sec to determine the breakdown voltage and the sustained time. The thickness was measured using a digital linear drop gauge from ONO SOKKI, model EG-225. Dielectric strength can be calculated as the breakdown voltage per unit of thickness.

### Example 1

### Single Firing of Multiple Layers

The filtered glass precursor composition described above (0.1 ml) was rod-coated onto an annealed, plasma-cleaned stainless steel substrate and dried, as described above.

The drawdown coating and drying cycle was repeated five times. The substrate was then fired, as described above.

Breakdown voltage was found to be 520-600 V DC at 10 randomly selected locations.

After firing, a 200 nm Mo coating was deposited on the fired glass layer via sputter vapor deposition.

### Example 2

### Deposition of a Single Layer which is then Fired, Followed by Deposition of Subsequent Layers which are Fired

The filtered glass precursor composition (0.1 ml) was rod-coated onto an annealed, plasma-cleaned stainless steel substrate and dried, as described above.

This layer was then fired as described above.

The drawdown coating and drying cycle was repeated under the same conditions five times. The coated substrate was fired a second time, and then a 200 nm Mo layer was deposited on the fired glass layer via sputter vapor deposition.

### Example 3

### Multiple Firing Process

The filtered glass precursor composition (0.1 ml) was rod-coated onto an annealed, plasma-cleaned stainless steel substrate and dried, as described above.

This layer was then fired as described above.

The cycle of coating, drying and firing steps was repeated five times.

A 200 nm Mo top electrode was deposited onto the fired glass layer via sputter vapor deposition.

### Example for Shingling Process

### Example 4

### Sodium Aluminoborosilicate Glass Composition having 12% Weight NA₂O Coated on Stainless Steel 430

A 0.5M precursor formulation with respect to [Si] was prepared in the following manner:

2.3466 g (11.26 mmol) of tetraethylorthosilicate (Sigma Aldrich, >99.0% purity) was dissolved in 10 ml of 1-butanol. To this solution, was added 1.5 mole equivalents of glacial acetic acid (1.0100 g; 16.89 mmol, EMD, >99.7% purity) and 1 drop (0.02 g) of nitric acid. The solution was then refluxed at 118° C. for 2 h. Upon reflux completion and in the following order of addition, 0.3448 g (3.59 mmol) of sodium propionate (Sigma Aldrich, >99% purity), 0.1179 g (0.36 mmol) of tris(acetylacetonato) aluminium (Sigma Aldrich, >99% purity) and 0.5054 g (3.46 mmol) of triethylborate (Sigma Aldrich, 99% purity) were added to the solution at room temperature. The solution was then stirred until clear and 1-butanol was added until the total volume of 25.00 ml was achieved.

A 50.8 micrometer thick stainless steel foil (430 ferritic stainless steel, from ATI) was diced to size and cleaned by rinsing the surface with methanol.

The glass precursor formulation was filtered using a 0.45 micron PTFE filter.

The cleaned stainless steel substrate was rod-coated with a #40 bar on a Cheminstrument® motorized drawdown coater with 0.1 ml of filtered glass precursor formulation at room temperature in a clean room environment (class 100). The coated sample was then dried at room temperature for 30 s, then at 150° C. for 2 minutes.

The drawdown coating and drying, cycle was repeated under the same conditions until the desired thickness was obtained.

The final layer was then fired to 500° C. for 2 minutes at a ramp rate of 10° C./s.

Cells were fabricated according to the procedure found in the following reference:
Gossla, M.; Shafarman, W. N., Thin solid films, 2005, 480-481, 33-36

### Example 5

### Sodium Aluminoborosilicate Glass Composition having 12% Weight NA₂O Coated on Stainless Steel 430

A 0.5M precursor formulation with respect to [Si] was prepared in the following manner:

2.3466 g (11.26 mmol) of tetraethylorthosilicate (Sigma Aldrich, >99.0% purity) was dissolved in 10 ml of 1-butanol. To this solution, was added 1.5 mole equivalents of glacial acetic acid (1.0100 g; 16.89 mmol, EMD, >99.7% purity) and 1 drop (0.02 g) of nitric acid. The solution was then refluxed at 118° C. for 2 h. Upon reflux completion and in the following order of addition, 0.3448 g (3.59 mmol) of sodium propionate (Sigma Aldrich, >99% purity), 0.1179 g (0.36 mmol) of tris(acetylacetonato) aluminium (Sigma Aldrich, >99% purity) and 0.5054 g (3.46 mmol) of triethylborate (Sigma Aldrich, 99% purity) were added to the solution at room temperature. The solution was then stirred until clear and 1-butanol was added until the total volume of 25.00 ml was achieved.

A 50.8 micrometer thick metal stainless steel foil 430 foil was diced to size and argon plasma cleaned (A.G. Services PE-PECVD System 1000) under the following conditions for a time of 30 s:
power=24.3 W
pressure=100.0 mTorr
throttle pressure=200.0 mTorr
argon gas flow=10.0 sccm

The glass precursor formulation was filtered using a 0.45 micron PTFE filter.

The cleaned metal foil substrate was rod-coated with a #40 bar on a Cheminstrument® motorized drawdown coater with 0.1 ml of filtered glass precursor formulation at room temperature in a clean room environment (class 100). The coated sample was then dried at room temperature for 30 s, then at 150° C. for 2 minutes.

The layer was then fired to 500° C. for 2 minutes at a ramp rate of 10° C./s.

The drawdown coating, drying and firing cycle was repeated under the same conditions until the desired thickness was obtained.

Cells were fabricated according to the following procedure found in Gossla, M.; Shafarman, W. N., Thin solid films, 2005, 480-481, 33-36

A 500 nm Mo coating was deposited via sputter vapour deposition.
A 1.7 um Cu(In_{0.7}Ga_{0.3})Se₂ coating was then deposited via an evaporation process.
A 70 nm CdS coating was the subsequently deposited via a wet bath deposition process.
A 120 nm aluminium zinc oxide layer was then deposited by sputtering

Finally, nickel/aluminium alloy or silver bus bars were evaporated to collect current.

### Example 6

### Sodium Aluminoborosilicate Glass Composition having 12% Weight NA₂O Coated on Stainless Steel 430

A 0.5M precursor formulation with respect to [Si] was prepared in the following manner:

2.3466 g (11.26 mmol) of tetraethylorthosilicate (Sigma Aldrich, >99.0% purity) was dissolved in 10 ml of 1-butanol. To this solution, was added 1.5 mole equivalents of glacial acetic acid (1.0100 g; 16.89 mmol, EMD, >99.7% purity) and 1 drop (0.02 g) of nitric acid. The solution was then refluxed at 118° C. for 2 h. Upon reflux completion and in the following order of addition, 0.3448 g (3.59 mmol) of sodium propionate (Sigma Aldrich, >99% purity), 0.1179 g (0.36 mmol) of tris(acetylacetonato) aluminium (Sigma Aldrich, >99% purity) and 0.5054 g (3.46 mmol) of triethylborate (Sigma Aldrich, 99% purity) were added to the solution at room temperature. The solution was then stirred until clear and 1-butanol was added until the total volume of 25.00 ml was achieved.

A 50.8 micrometer thick metal stainless steel foil 430 foil was diced to size and cleaned by rinsing the surface with methanol and by argon plasma treatment (A.G. Services PE-PECVD System 1000) under the following conditions for a time of 30 s:
power=24.3 W
pressure=100.0 mTorr
throttle pressure=200.0 mTorr
argon gas flow=10.0 sccm

The glass precursor formulation was filtered using a 0.45 micron PTFE filter.

The cleaned metal foil substrate was rod-coated with a #40 bar on a Cheminstrument® motorized drawdown coater with 0.1 ml of filtered glass precursor formulation at room temperature in a clean room environment (class 100). The coated sample was then dried at room temperature for 30 s, then at 150° C. for 2 minutes.

The layer was then fired to 500° C. for 2 minutes at a ramp rate of 10° C./s.

The drawdown coating, drying and firing cycle was repeated under the same conditions until the desired thickness was obtained.

What is claimed is:

1. A process comprising:
a) depositing a glass precursor directly onto at least a portion of a surface of a flexible substrate, and
b) heating the glass precursor to form a glass layer on at least a portion of the substrate, wherein the glass layer comprises SiO₂, Al₂O₃, Na₂O, and B₂O₃, and optionally a metal oxide.

2. The process of claim 1 wherein the flexible substrate is a metal.

3. The process of claim 2 wherein the metal is stainless steel.

4. The process of claim 3 wherein the stainless steel comprises from 3 to 3.95 wt % aluminum.

5. The process of claim 3 wherein the stainless steel comprises about 22 wt % chromium and about 5.8 wt % aluminum and wherein the balance is iron.

6. The process of claim 2 wherein the metal is a metal selected from the group consisting of: aluminum; titanium; molybdenum; nickel; vanadium; chromium; silver; and gold.

7. The process of claim 1 wherein the glass layer comprises a sodium ion source in an amount of from about 1 to about 25 wt % by weight of the glass layer.

8. The process of claim 7 wherein the sodium ion source is present in an amount of from about 4 to about 18 wt %.

9. The process of claim 8 wherein the sodium ion source is present in an amount of from about 4 to about 16 wt %.

10. A multi-layer article comprising:
a) a flexible metal substrate layer;
b) a glass layer disposed directly on at least a portion of the flexible substrate, wherein the glass layer comprises SiO₂, Al₂O₃, Na₂O, B₂O₃ and, optionally, a metal oxide.

11. The multi-layer article of claim 1, further comprising:
c) a conductive layer disposed on at least a portion of the glass layer.

12. The multi-layer article of claim 11, wherein the conductive layer comprises material selected from the group consisting of metals, oxide-doped metals, metal oxides, organic conductors, and combinations thereof.

13. The multi-layer article of claim 12, wherein the conductive layer comprises molybdenum.

14. The multi-layer article of claim 12, wherein the flexible metal substrate is in the form of a sheet.

15. The multilayer article of claim 11, further comprising:
d) a photoactive layer disposed on the conductive layer;
e) a CdS layer disposed on the photoactive layer; and
f) a transparent conductive oxide disposed on the CdS layer.

16. The multilayer article of claim 15, wherein the photoactive layer comprises CIGS, CIS or CZTS-Se.

17. The multilayer article of claim 15, wherein the transparent conductive oxide is selected from the group consisting of doped zinc oxide and indium tin oxide.

18. The multilayer article of claim 10 wherein the substrate is stainless steel.

19. The multilayer substrate of claim 10 wherein the substrate is a metal selected from the group consisting of: aluminum; titanium; molybdenum;
nickel; vanadium; chromium; silver; and gold.

20. The article of claim 10 wherein the glass layer comprises a sodium ion source in an amount of from about 1 to about 25 wt % by weight of the glass layer.

21. The article of claim 20 wherein the glass layer comprises a sodium ion source in an amount of from about 4 to about 18 wt % by weight of the glass layer.

22. The article of claim 21 wherein the glass layer comprises a sodium ion source in an amount of from about 4 to about 16 wt % by weight of the glass layer.
